(19) United States
(12) Patent Application Publication
(10) Pub. No.: US 2001/0027550 A1
(43) Pub. Date: Oct. 4, 2001

(54) CD-ROM decoder

(76) Inventors: Takayuki Suzuki, Gifu-shi (JP); Hiroyuki Tsuda, Ichinomiya-shi (JP); Masayuki Ishibashi, Yao-shi (JP)

Correspondence Address: Douglas W. Swartz, SHERIDAN ROSS P.C., Suite 1200, 1560 Broadway, Denver, CO, 80202-5141, US

(21) Appl. No.: 09/818,048

(22) Filed: Mar. 27, 2001

(30) Foreign Application Priority Data
Mar. 28, 2000 (JP) 2000-088209

(51) Int. Cl. G11C 29/00

(52) U.S. Cl. 714/763

(57) ABSTRACT

A CD-ROM decoder that reduces the load on a microcomputer. The CD-ROM decoder temporarily stores in a buffer memory in sector units digital data. The CD-ROM decoder processes the digital data by correcting and detecting code errors included in the digital data. The CD-ROM decoder includes a first counter for counting the number of sectors of the digital data temporarily stored in the buffer memory to generate a first count value and a second counter for counting the number of sectors of the processed digital data transferred from the buffer memory to generate a second count value. A first buffering control circuit deciding an unused capacity of the buffer memory based on the first and second count values to stop the storing of the digital data to the buffer memory when the unused capacity is equal to or less than a predetermined value.

### BACKGROUD OF THE INVENTION

The present invention relates to a CD-ROM decoder, and more particularly, to a CD-ROM decoder for correcting code errors included in digital data and transferring the corrected digital data to a computer.

FIG. 1 is a schematic block diagram of a prior art CD-ROM system 100. The CD-ROM system 100 includes a pickup 2, an analog signal processor 3, a digital signal processor 4, a CD-ROM decoder 5, a buffer RAM 6, and a microcomputer 7.

A spiral record track is defined on the disc 1. Digital data complying with a predetermined format is recorded along the record track. The digital data is generated through eight to fourteen modulation (EFM). The disc 1 is rotated at a constant linear velocity or a constant angular velocity.

The pickup 2 emits a laser beam against the disc 1 and generates from the reflected laser beam a voltage signal corresponding to the digital data recorded on the disc 1.

The analog signal processor 3 shapes the waveform of the voltage signal in correspondence with the fluctuation of the voltage signal provided from the pickup 2 to generate an EFM signal.

The digital signal processor 4 performs EFM demodulation on the EFM signal provided from the analog signal processor 3 to covert the 14-bit digital data to 8bit digital data and generates CD-ROM data. Further, the digital signal processor 4 uses a cross interleave Reed-Solomon code (CIRC) to detect and correct code errors. A frame is defined by 24 bytes of CD-ROM data. With reference to FIG. 2, a sector is defined by 2,352 (98 frames×24) bytes of CD=ROM data. A synchronization signal (12 bytes) and a header (4 bytes) are allocated to the head of each sector. The synchronization signal has a fixed pattern and indicates the head of each sector. Absolute time information (minutes/seconds/frame number: each 1 byte) and a mode identification code (1 byte) are included in the header. The absolute time information corresponds to an address on the disc 1. The mode identification code is used to identify the format (mode) of the data in a sector. In accordance with the mode and form, user data, an error correction code (ECC), and an error detection code (EDC) are allocated to the 2,336 bytes following the header. For example, referring to FIG. 3, in mode 1, the user data (2,048 bytes), the EDC (4 bytes), ZERO (8 bytes), and the ECC (276 bytes) follow the header. In mode 2 formless, only the user data (2,336 bytes) follows the header. In form 1 of mode 2, a sub-header (8 bytes), user data (2,048 bytes), the EDC (4 bytes), and the ECC (276 bytes) follow the header. In form 2 of mode 2, the sub-header (8 bytes), the user data (2,334 bytes), and the EDC (4 bytes) follow the header.

The CD-ROM decoder 5 also corrects error codes included in the CD-ROM data provided from the digital signal processor 4 and transfers CD-ROM data (user data) to a host computer based on a request from the host computer.

The buffer RAM 6 is connected to the CD-ROM decoder 5 to store CD-ROM data in sector units for a predetermined time. The CD-ROM decoder 5 performs decoding to correct code errors in the CD-ROM data during the predetermined time.

The microcomputer 7 executes a predetermined control program so that the analog signal processor 3, the digital signal processor 4, and the CD-ROM decoder 5 are operated at predetermined timings. In response to a transfer request of the CD-ROM data from the host computer, the microcomputer 7 controls the analog signal processor 3, the digital signal processor 4, and the CD-ROM decoder 5 to transfer the requested data to the host computer.

The microcomputer 7 detects address information (minutes/seconds/frame number) and sector information (sector format) of the sector preceding the sector from which buffering is to be started from a header information register of the CD-ROM decoder 5 and causes the CD-ROM decode 5 to start buffering data based on the information. The microcomputer 7 stops buffering data in the same way it started the buffering. The microcomputer 7 further monitors the data amount of the buffer RAM 6 during the buffering to manage the buffer RAM 6.

Accordingly, the buffering of the CD-ROM data to the buffer RAM 6 is performed by the microcomputer 7. Further, the processes described above, including the data buffering, are properly performed in accordance with a control program. However, an increase in the operating speed of the CD-ROM system 100 increases the load on the microcomputer 7. As a result, the microcomputer 7 may not be able to follow the operations of the analog signal processor 3, the digital signal processor 4, and the CD-ROM decoder 5.

### SUMMARY OF THE INVENTION

It is an object of the present invention to provide a CD-ROM decoder that decreases the load on the microcomputer, while appropriately performing buffering control.

To achieve the above object, the present invention provides a CD-ROM decoder for temporarily storing in a buffer memory in sector units digital data having a predetermined number of bytes and a predetermined format, processing the digital data by correcting and detecting code errors included in the digital data, and transferring the processed digital data. The CD-ROM decoder includes a first counter for counting the number of sectors of the digital data temporarily stored in the buffer memory to generate a first count value. A second counter counts the number of sectors of the processed digital data transferred from the buffer memory to generate a second count value. A first buffering control circuit is connected to the first and second counters for deciding an unused capacity of the buffer memory based on the first and second count values to stop the storing of the digital data to the buffer memory when the unused capacity is equal to or less than a predetermined value.

The present invention also provides a CD-ROM decoder for temporarily storing in a buffer memory in sector units digital data having a predetermined number of bytes and a predetermined format, processing the digital data by selectively correcting and detecting code errors included in the digital data, and transferring the processed digital data. The digital sector of each sector includes a sector address. The CD-ROM decoder includes a first counter for counting the number of sectors of the digital data temporarily stored in the buffer memory to generate a first count value. A second counter counts the number of sectors of the processed digital data transferred from the buffer memory to generate a second count value. A first buffering control circuit connected to the first and second counters for deciding an unused capacity of the buffer memory based on the first and second counter values to temporarily stop the storing of the digital data to the buffer memory when the unused capacity is equal to or less than a predetermined value. After the storing of the digital data to the buffer memory is stopped, the first buffering control circuit restarts the storing of the digital data to the buffer memory when the unused capacity reaches the predetermined value. A first register stores a target address of a sector from which to start the storing of the digital data to the buffer memory. A second register stores a number of the sectors of the digital data that is to be stored in the buffer memory. A third register stores a sector address that is included in the digital data. A second buffering control circuit is connected to the first, second, and third registers to determine from the target address and the sector address when to start the storing of the digital data to the buffer memory and to determine from the sector number when to end the storing of the digital data to the buffer memory.

The present invention further provides a method for transferring in sector units digital data having a predetermined number of bytes and a predetermined format with a CD-ROM decoder. The CD-ROM decoder includes a buffering control circuit. The method includes counting the number of sectors of the digital data temporarily stored in the buffer memory to generate a first count value, counting the number of sectors of the processed digital data transferred from the buffer memory to generate a second count value, deciding an unused capacity of the buffer memory based on the first and second count values with a buffering control circuit, and stopping the storing of the digital data to the buffer memory with the buffering control circuit when the unused capacity is equal to or less than a predetermined value.

Other aspects and advantages of the present invention will become apparent from the following description, taken in conjunction with the accompanying drawings, illustrating by way of example the principles of the invention.

### BRIEF DESCRIPTION OF THE DRAWINGS

The invention, together with objects and advantages thereof, may best be understood by reference to the following description of the presently preferred embodiments together with the accompanying drawings in which:

FIG. 1 is a schematic block diagram of a prior art CDROM system;

FIG. 2 is a diagram illustrating the structure of a sector of CD-ROM data;

FIG. 3 is a diagram illustrating formats of a sector of CD-ROM data;

FIGS. 4A and 4B are schematic block diagrams of a CDROM decoder according to a preferred embodiment of the present invention;

FIG. 5 is a schematic diagram illustrating the memory area of a buffer RAM; and

FIG. 6 is a flowchart illustrating the determination of a sector type in the CD-ROM decoder of FIGS. 4A and 4B.

### DETAILED DESCRIPTION OF THE PREFERRED EMBODIMENTS

In the drawings, like numerals are used for like elements throughout.

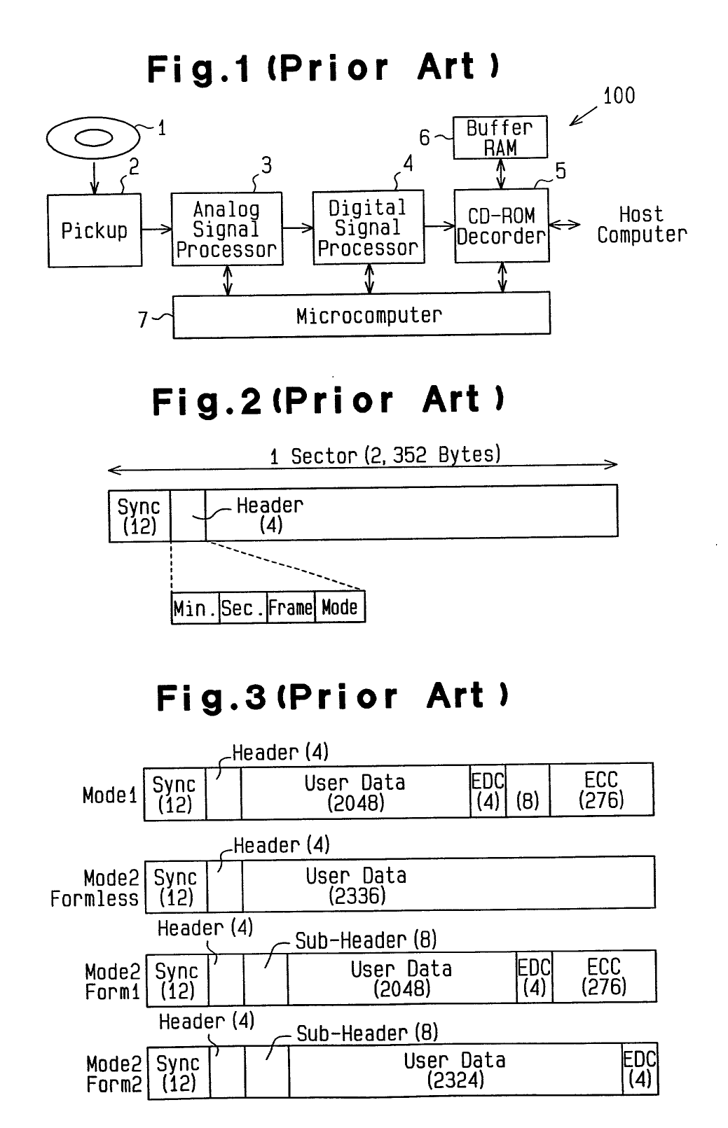

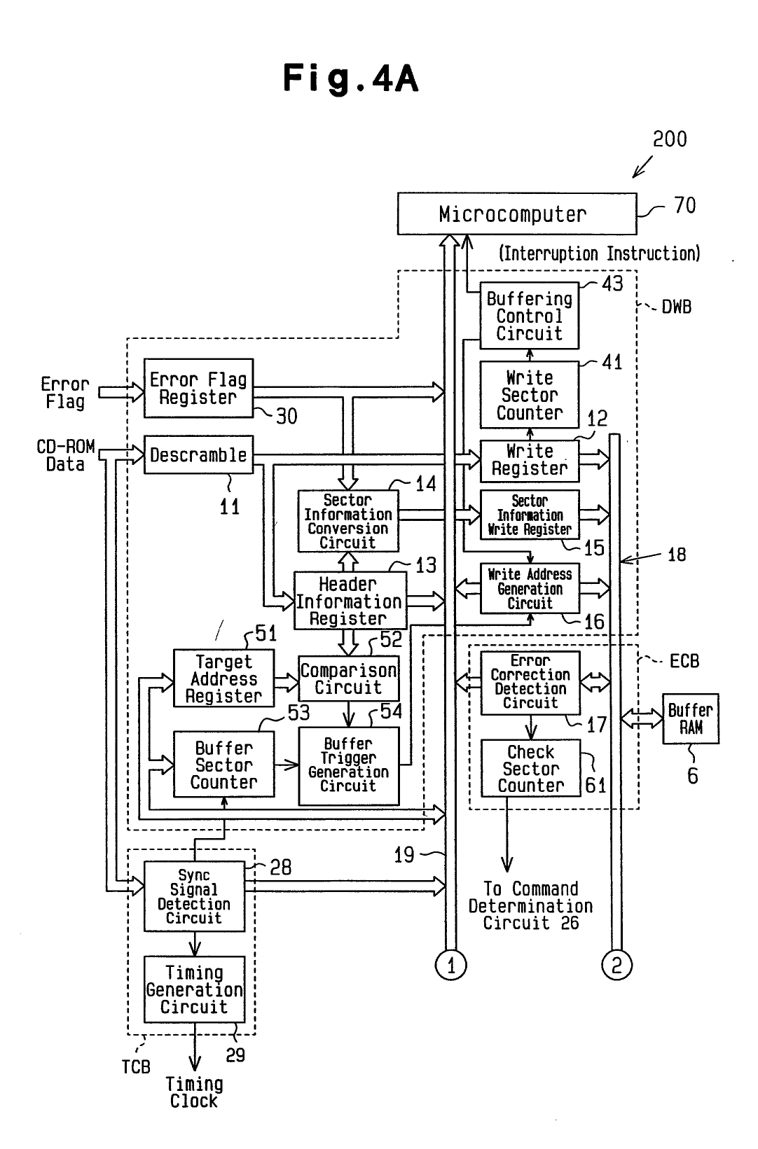

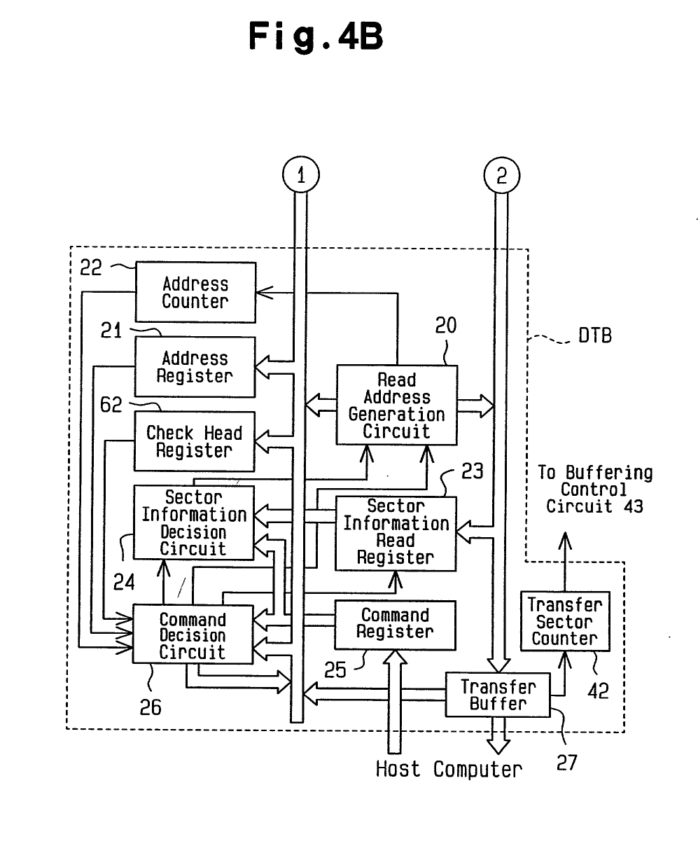

FIGS. 4A and 4B show a CD-ROM decoder 200 according to a first embodiment of the present invention. The CD-ROM decoder 200 is used in lieu of the CD-ROM decoder 100 of FIG. 1 and connected to the buffer RAM 6 and a microcomputer 70.

The CD-ROM decoder 200 includes a data write circuit DWB, an error check circuit ECB, a data transfer circuit DTB, and a timing adjustment circuit TCB. The data write circuit DWB stores CD-ROM data in the buffer RAM 6. The error check circuit ECB detects and corrects write data errors. The data transfer circuit DTB transfers the data stored in the buffer RAM 6 to a host computer. The timing adjustment circuit TCB adjusts the timing of the data write circuit DWB, the error check circuit ECB, and the data transfer circuit DTB.

The data write circuit DWB includes a descramble circuit 11, a write register 12, a header information register 13, a sector information conversion circuit 14, a sector information write register 15, a write address generation circuit 16, an error flag register 30, a write sector counter 41, a buffering control circuit 43, a target address register 51, a comparison circuit 52, a buffer sector counter 53, and a buffer trigger generation circuit 54.

Except for the 12 bytes of the synchronization signal, the descramble circuit 11 descrambles the 2,340 bytes of data in each sector of CD-ROM data. The descramble circuit 11 then generates descrambled CD-ROM data having a predetermined format.

The write register 12 receives CD-ROM data from the descramble circuit 11 and writes the CD-ROM data to the buffer RAM 6 via a first data bus 18. The write register 12 is connected to the write sector counter 41. The write sector counter 41 counts the number of sectors in the CD-ROM data written to the buffer RAM 6 and provides a count value CB to the buffering control circuit 43.

The buffering control circuit 43 performs buffering management based on the count value CB and a count value CT of a transfer sector counter 42.

The header information register 13 extracts 4-byte header information from the CD-ROM data provided by the descramble circuit 11 and transfers the header information to the microcomputer 70 via a second data bus 19. The header information register 13 extracts 8 bytes of data following the header as a sub-header and provides the header and the sub-header to the sector information conversion circuit 14.

The sector information conversion circuit 14 determines the mode of the CD-ROM data based on the header information. When the CD-ROM data is in mode 2, the sector information conversion circuit 14 determines the form based on the sub-header information. In accordance with the determination result, the sector information conversion circuit 14 generates 3 bits of sector information indicating the format of the CD-ROM data in each sector and provides the sector information to the sector information write register 15.

The sector information write register 15 receives the sector information from the sector information conversion circuit 14 and writes the sector information to the buffer RAM 6 via the first data bus 18.

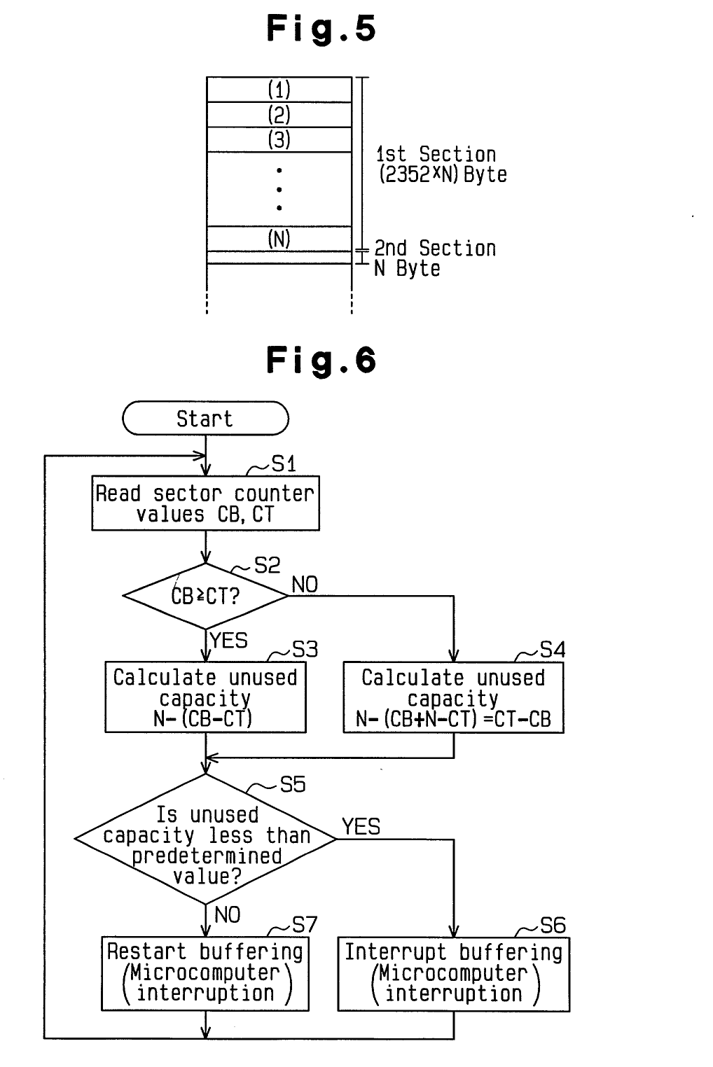

The buffer RAM 6 has sufficient capacity for storing CD-ROM data having a predetermined number of sectors to transfer data to the host computer. Referring to FIG. 5, the buffer RAM 6 has first sections, which store 2,352×N bytes of CD-ROM data, and second sections following the associated first sections to store N bytes of sector information. This associates the CD-ROM data and the sector information (the format information of data) in sector units in the buffer RAM 6.

The write address generation circuit 16 generates an address designating the area for a sector in one of the first sections of the buffer RAM 6 and designates a write address in the buffer RAM 6 for the CD-ROM data stored in the write register 12. The write address, which includes an address corresponding to data at the head of a sector, is provided from the write address generation circuit 16 to an address register 21 via the second data bus 19. Simultaneously, the write address generation circuit 16 generates an address designating an area having one byte in the second sections of the buffer RAM 6 and designates the write address for writing the sector information stored in the sector information write register 15 to the buffer RAM 6. The sector information write address is provided to the address register 21.

The error flag register 30 receives an error flag indicating that an error was not corrected during the error correction process and transfers the error flag to the microcomputer 70 via the second data bus 19.

A target address register 51 stores target address information provided from a microcomputer 70 via the second data bus 19 and repetitively provides the target address information to the comparison circuit 52. The target address information indicates the address of the sector at the head of the CD-ROM data requested from the host computer and is generated by the microcomputer 70 in response to an instruction from the host computer.

The comparison circuit 52 compares the target address information provided from the target address register 51 with the data address information provided from a header information register 13 to generate a buffering start pulse signal when the two pieces of information match.

The buffer sector counter 53 receives buffering sector information from the microcomputer 70 as preset data. The buffering sector information indicates the number of sectors that are to be buffered (transferred) and is generated in response to an instruction from the host computer. The buffer sector counter 53 counts downward whenever a sector of the CD-ROM data is provided in response to a timing signal, which is provided by a synchronization signal detection circuit 28. When the count value returns to an initial value (zero), the buffer sector counter 53 generates a buffering stop pulse signal.

The buffer trigger generation circuit 54 instructs the buffering to be started when the buffering start pulse signal goes high. Further, the buffer trigger generation circuit 54 instructs the buffering to be stopped when the buffering stop pulse signal goes high.

The target address register 51, the comparison circuit 52, the buffer sector counter 53, and the buffer trigger generation circuit 54 automatically start and stop buffering in response to a transfer request from a host computer.

The error check circuit ECB includes an error correction detection circuit 17 and a check sector counter 61.

The error correction detection circuit 17 corrects and detects errors in the CD-ROM data written to the buffer RAM 6. The error correction detection circuit 17 receives the CD-ROM data and sector information in single sector units from the buffer RAM 6, determines the process to be carried out on the CD-ROM data based on the sector information, corrects code errors with the ECC, and detects code errors with the EDC. For example, if the sector information is in mode 1 or in form 1 of mode 2, error correction and error detection are performed. If the sector information is form 2 of mode 2, only error detection is performed. The CD-ROM data that has undergone a predetermined process is stored again in the buffer RAM 6 to be transferred to the host computer.

In response to a timing signal, the check sector counter 61 counts the number of sectors that have undergone a predetermined error check in the error correction detection circuit 17.

The data transfer circuit DTB includes a read address generation circuit 20, the address register 21, an address counter 22, a sector information read register 23, a sector information determination circuit 24, a command register 25, the command determination circuit 26, a transfer buffer 27, and the check head register 62. The read address generation circuit 20, the address register 21, the sector information determination circuit 24, and the command determination circuit 26 configure a data transfer circuit. The data transfer circuit checks the flag bit of the transfer request command stored in the command register 25 and determines the data transfer byte number per sector and transfers data in correspondence with the data transfer byte number to the host computer.

In response to instructions from the sector information determination circuit 24 and the command determination circuit 26, the read address generation circuit 20 generates addresses designating the first and second sections of the buffer RAM 6. Based on the address, the sector information and the CD-ROM data (user data) are read from the buffer RAM 6. The read sector information is temporarily stored in the sector information read register 23. The read user data is provided to the transfer buffer 27 via the first data bus 18, and the user data is transferred to the host computer from the transfer buffer 27.

The address register 21 receives from the write address generation circuit 16 the write address corresponding to the data at the head of each sector and the write address corresponding to the sector information. Simultaneously, among the plural pieces of sector time information stored in the buffer RAM 6, the address register 21 stores the smallest piece of time information or the largest piece of time information. This enables recognition of the time information of all of the sectors stored in the buffer RAM 6.

The address counter 22 increments its count value each time the read address generation circuit 20 updates the read address and provides the count value to the command determination circuit 26. The address counter 22 is operated when the read address generation circuit 20 provides the read address to the buffer RAM 6 and counts the sector number (or the byte number) of the data read from the buffer RAM 6.

The check head register 62 stores the address of the head sector checked by the error correction detection circuit 17 and stored in the buffer RAM 6.

The sector information determination circuit 24 determines the format of the CD-ROM data of the sector corresponding to the sector information based on the sector information stored in the sector information read register 23. The sector information determination circuit 24 sets an offset value added to the read address by the read address generation circuit 20 in accordance with the format of the CD-ROM data when transferring data to the host computer. In other words, user data excluding the header and the sub-header is transferred to the host computer. Thus, in accordance with the format of each sector, the addresses of the header and the sub-header are added to the head address as an offset value. When all of the CD-ROM data (2,352 bytes) in a sector is transferred, offsetting is not necessary. The command determination circuit 26 determines whether offsetting is necessary based on the instruction from the host computer.

The sector information determination circuit 24 is provided with the sector information included in the transfer request command from the host computer via the command register 25. Further, the sector information determination circuit 24 determines whether the sector information generated by the sector information conversion circuit 14 matches the sector information of the transfer request command (flag bit indicating the sector format). The sector information determination circuit 24 sets the offset value if the two pieces of information match, and notifies the microcomputer 70 of an error if the two pieces of information do not match.

The command register 25 temporarily stores the transfer request command provided from the host computer.

The command determination circuit 26 sends operating instructions to the read address generation circuit 20 and the sector information read register 23 based on the address of the head data of each sector stored in the address register 21, the count value of the address counter 22, and the transfer request command stored in the command register 25. Based on the information of the check head register 62, the command determination circuit 26 determines whether the data corresponding to the transfer request of the host computer has been checked for errors and stored in the buffer RAM 6.

The transfer buffer 27 receives user data read from the buffer RAM 6 via the first data bus 18 and transfers the user data to the host computer. The transfer buffer 27 is connected to the transfer sector counter 42. The transfer sector counter 42 counts the sector number of the user data transferred to the host computer and provides the count value CT to the buffering control circuit 43.

The timing adjustment circuit TCB includes the synchronization signal detection circuit 28 and a timing generation circuit 29. The synchronization signal detection circuit 28 detects 12 bytes of the synchronization signal at the head of each sector of the CD-ROM data and provides the timing generation circuit 29 with a timing signal indicating the beginning of a sector. The synchronization signal detection circuit 28 provides error detection data to the microcomputer 70 via the second data bus 19 when the synchronization signal is not detected.

The timing generation circuit 29 receives the timing signal from the synchronization signal detection circuit 28 and generates various timing clock signals for determining the operating timing of the microcomputer 70, the data write circuit DWB, the error check circuit ECB, and the data transfer circuit DTB.

In the CD-ROM decoder 200, the data write circuit DWB and the data transfer circuit DTB are operated in accordance with the timing clock signal, and the transfer of CD-ROM data is performed automatically without being controlled by the microcomputer 70.

When the host computer requests a certain sector to be transferred from the host computer, the command determination circuit 26 refers to the address information and the time information held in the address register 21 or the check head register 62 to determine whether the requested sector (target sector) is stored in the buffer RAM 6. If the target sector is stored in the buffer RAM 6, the sector information determination circuit 24 receives the sector information corresponding to the target sector from the sector information read register 23 and determines the format of the target sector from the sector information.

Subsequently, if the host computer requests for the transfer of only the user data, the sector information determination circuit 24 instructs the read address generation circuit 20 to generate an offset address, which is the offset head address, based on the determined format. The user data of the target sector is read from the buffer RAM 6 based on the offset address. For example, if the format of the target sector is mode 1, the user data of the target sector is read from the offset address obtained by adding the 12 byes of the synchronization signal and the 4 bytes of the header to the head address stored in the address register 21.

When the reading of the user data starts, the address counter 22 counts the byte number of the user data read from the buffer RAM 6. When the byte number of the read user data reaches the byte number instructed by the host computer, the command determination circuit 26 instructs the read address generation circuit 20 to stop reading data. In this manner, the data stored in the buffer RAM 6 is automatically transferred to the host computer without being controlled by the microcomputer 70.

If the command determination circuit 26 determines that the CD-ROM data of the target sector is not stored in the buffer RAM 6, the command determination circuit 26 sends a new CD-ROM data read (buffering) instruction to the microcomputer 70 via the second data bus 19. In response to the instruction, the microcomputer 70 activates the pickup 2 (FIG. 1) and controls the analog signal processor 3, the digital signal processor 4, and the CD-ROM decoder 200 to read the CD-ROM, which includes the target sector. When the target sector is stored in the buffer RAM 6, the above automatic transfer process is performed.

The buffering control of the CD-ROM decoder 200 will now be described.

Buffering in response to a transfer request from the host computer is performed in the following manner. The comparison circuit 52 compares the target address information provided from the target address register 51 with the data address information provided from the header information register 13. The comparison circuit 52 asserts a buffering start pulse signal when the target address information and the data address information match. In response to the buffering start pulse signal, the buffer trigger generation circuit 54 instructs the write address generation circuit 16 to start the buffering.

The buffering ends in the following manner. When the buffer sector counter 53 receives preset data from the microcomputer 70, the buffer sector counter 53 counts downward. When the count value returns to an initial value (zero), the buffer sector counter 53 causes a buffering stop pulse signal to go high. In response to the buffering stop pulse signal, the buffer trigger generation circuit 54 instructs the write address generation circuit 16 to stop the buffering.

In addition to the starting and ending control of the buffering, interruption and restarting control of the buffering is performed in the CD-ROM decoder 200. The buffering interruption and restart control will now be discussed with reference to the flowchart of FIG. 6.

The buffering interruption and restarting control is performed by the buffering control circuit 43 based on the count value CB of the write sector counter 41 and the count value CT of the transfer sector counter 42. The timing for interrupting and restarting the buffering is adjusted in accordance with the timing clock signal provided from the timing generation circuit 29. The buffering control circuit 43 includes known logic circuits, such as a comparison circuit (not shown) for comparing data and an adding circuit (not shown) for adding data.

Referring to FIG. 6, at step S1, the count value CB of the write sector counter 41 and the count value CT of the transfer sector counter 42 are provided to the buffering control circuit 43. The write sector counter 41 and the transfer sector counter 42 each count the number of sectors from 0 to N and returns the count value to 0 when the count number exceeds N. N is a value set in accordance with the capacity of the buffer RAM 6 and corresponds to the sector number of storable data in the buffer RAM 6.

At step S2, the count value CB and the count value CT are compared. If the count value CB is equal to or greater than the count value CT, a used capacity (CB−CT) is subtracted from “N” to calculate an unused capacity (sector number).

If the count value CB is smaller than the count value CT, at step S4, a used capacity (CB+N−CT) is subtracted from N to calculate an unused capacity (CT−CB). That is, when the count value CB is smaller than the count value CT, the unused capacity of the buffer RAM 6 is calculated from the count value difference (CT−CB).

At step S5, the buffering control circuit 43, the buffering control circuit 43 determines whether the unused capacity of the buffer RAM 6 is less than a predetermined value (e.g., 0 (zero)). If the unused capacity is less than the predetermined value, at step S6, the buffering of data to the buffer RAM 6 is interrupted. If the unused capacity is less than the predetermined value, the buffer RAM 6 is substantially full and can no longer buffer the CD-ROM data. Accordingly, the buffering operation is temporarily interrupted until the buffer RAM 6 has the predetermined unused capacity.

More specifically, the buffering control circuit 43 provides the write address generation circuit 16 with a signal that stops address generation to perform buffering. Further, the buffering control circuit 43 provides the microcomputer 70 with an interruption signal for interrupting the transfer of the CD-ROM data to the CD-ROM decoder 200.

At step S5, if the unused capacity of the buffer RAM 6 is equal to or greater than the predetermined value, the buffering control circuit 43 proceeds to step S7 and continues the buffering. In other words, if the unused capacity is equal to or greater than the predetermined value, the buffer RAM 6 has unused capacity. The predetermined value is used as a criterion for determining whether to restart the buffering after the buffering is interrupted.

More specifically, the buffering control circuit 43 provides the write address generation circuit 16 with a signal that restarts address generation for buffering. Further, the buffering control circuit 43 provides the microcomputer 70 with an interruption signal for restarting the transfer of the CD-ROM data to the CD-ROM decoder 200. The buffering is automatically restarted in this manner. The buffering interruption and restart is repeated until the buffering of the predetermined number of sectors is completed. The predetermined value, which is a determination criterion of the unused capacity in the buffer RAM, may be changed when required. For example, the predetermined value may be greater than the predetermined value used to determine buffering interruption.

The CD-ROM decoder 200 of the present invention has the advantages described below.

(1) The starting and ending control of the transfer data buffering is performed automatically by the buffer trigger generation circuit 54 and the address generation circuit 16. This reduces the load on the microcomputer 70 during the buffering starting and ending control.

(2) The buffering interruption and restart control is performed by the buffering control circuit 43. This also reduces the load on the microcomputer 70 during the buffering interruption and restart control. Accordingly, the microcomputer 70 is applicable to a CD-ROM system having a higher speed and an increased transfer data amount. Further, the buffering operation is performed in accordance with the high-speed operation of the CD-ROM system.

(3) The determination of the buffering interruption and restart, which is based on the difference between the count value CB and the count value CT, is performed by a simple circuit.

(4) The buffer RAM 6 stores CD-ROM data and the sector information, which indicates the format of the CD-ROM data in each sector. Accordingly, the operation control of the error correction detection circuit 17 using the sector information and the transfer control of the user data to the host computer are easily performed. In this state, the microcomputer 70 does not have to identify the sector format from the header information. This reduces the load on the microcomputer 70.

(5) Without being controlled by the microcomputer 70, the data transfer circuit DTB, which includes the address register 21, the address counter 22, the sector information read register 23, the sector information determination circuit 24, the command register 25, and the command determination circuit 26, automatically transfers the CD-ROM data stored in the buffer RAM 6 to the host computer.

It should be apparent to those skilled in the art that the present invention may be embodied in many other specific forms without departing from the spirit or scope of the invention. Particularly, it should be understood that the present invention may be embodied in the following forms.

The buffering control may be performed by counting the CD-ROM data amount in byte units instead of counting the CDROM data amount in sector units.

The buffering control may be performed by, for example, referring to the count value of the check sector counter 61 in addition to the count values of the write sector counter 41 and the transfer sector counter 42.

The sector information write register 15 need not be provided. For example, the sector information may be transferred from the sector information conversion circuit 14 to the microcomputer 70. Alternatively, a memory may be provided to store the sector information. Such configurations also reduce the load resulting from the transfer of CD-ROM data in the microcomputer 70.

The buffer sector counter 53 may function as an up-counter that generates a buffering stop pulse signal when the count value reaches the buffering request sector number.

The buffering starting and ending control may be performed by the microcomputer 70, and the buffering interruption and restart control may be performed by the CDROM decoder 200.

The present examples and embodiments are to be considered as illustrative and not restrictive, and the invention is not to be limited to the details given herein, but may be modified within the scope and equivalence of the appended claims.

What is claimed is:

1. A CD-ROM decoder for temporarily storing in a buffer memory in sector units digital data having a predetermined number of bytes and a predetermined format, processing the digital data by correcting and detecting code errors included in the digital data, and transferring the processed digital data, the CD-ROM decoder comprising:
a first counter for counting the number of sectors of the digital data temporarily stored in the buffer memory to generate a first count value;
a second counter for counting the number of sectors of the processed digital data transferred from the buffer memory to generate a second count value; and
a first buffering control circuit connected to the first and second counters for deciding an unused capacity of the buffer memory based on the first and second count values to stop the storing of the digital data to the buffer memory when the unused capacity is equal to or less than a predetermined value.

2. The CD-ROM decoder according to claim 1, wherein, after the storing of the digital data to the buffer memory is stopped, the first buffering control circuit restarts the storing of the digital data to the buffer memory when the unused capacity reaches the predetermined value.

3. The CD-ROM decoder according to claim 1, wherein the first buffering control circuit compares the first and second count values to determine the unused capacity of the buffer memory.

4. The CD-ROM decoder according to claim 1, wherein the digital data of each sector includes a sector address, the CD-ROM decoder further comprising:
a first register for storing a target address of a sector from which to start the storing of the digital data to the buffer memory;
a second register for storing a number of the sectors of the digital data that is to be stored in the buffer memory;
a third register for storing a sector address that is included in the digital data; and
a second buffering control circuit connected to the first, second, and third registers to determine from the target address and the sector address when to start the storing of the digital data to the buffer memory and to determine from the sector number when to end the storing of the digital data to the buffer memory.

5. The CD-ROM decoder according to claim 4, wherein the second buffering control circuit includes:
a comparison circuit connected to the first and third register for comparing the target address and the sector address to generate a buffering start signal when the target address and the sector address match; and
a buffer trigger generation circuit connected to the second register and the comparison circuit for determining when to start the storing of the digital data to the buffer memory in response to the buffering start signal.

6. The CD-ROM decoder according to claim 5, wherein the second register generates a buffering stop signal when the sector number reaches an initial value, and the buffer trigger generation circuit determines when to end the storing of the digital data to the buffer memory in response to the buffering stop signal.

7. A CD-ROM decoder for temporarily storing in a buffer memory in sector units digital data having a predetermined number of bytes and a predetermined format, processing the digital data by selectively correcting and detecting code errors included in the digital data, and transferring the processed digital data, wherein the digital sector of each sector includes a sector address, the CD-ROM decoder comprising:
a first counter for counting the number of sectors of the digital data temporarily stored in the buffer memory to generate a first count value;
a second counter for counting the number of sectors of the processed digital data transferred from the buffer memory to generate a second count value; and
a first buffering control circuit connected to the first and second counters for deciding an unused capacity of the buffer memory based on the first and second counter values to temporarily stop the storing of the digital data to the buffer memory when the unused capacity is equal to or less than a predetermined value, wherein, after the storing of the digital data to the buffer memory is stopped, the first buffering control circuit restarts the storing of the digital data to the buffer memory when the unused capacity reaches the predetermined value;
a first register for storing a target address of a sector from which to start the storing of the digital data to the buffer memory;
a second register for storing a number of the sectors of the digital data that is to be stored in the buffer memory;
a third register for storing a sector address that is included in the digital data; and
a second buffering control circuit connected to the first, second, and third registers to determine from the target address and the sector address when to start the storing of the digital data to the buffer memory and to determine from the sector number when to end the storing of the digital data to the buffer memory.

8. A method for transferring in sector units digital data having a predetermined number of bytes and a predetermined format with a CD-ROM decoder, wherein the CDROM decoder includes a buffering control circuit, the method comprising the steps of:
counting the number of sectors of the digital data temporarily stored in the buffer memory to generate a first count value;
counting the number of sectors of the processed digital data transferred from the buffer memory to generate a second count value;
deciding an unused capacity of the buffer memory based on the first and second count values with a buffering control circuit; and
stopping the storing of the digital data to the buffer memory with the buffering control circuit when the unused capacity is equal to or less than a predetermined value.
